(19) United States
(12) Patent Application Publication
(10) Pub. No.: US 2008/0299734 A1
(43) Pub. Date: Dec. 4, 2008

(54) Method of manufacturing a self-aligned fin field effect transistor (FinFET) device

(76) Inventors: Tzung-Han Lee, Taipei City (TW); Chin-Tien Yang, Kaohsiung County (TW)

Correspondence Address: NORTH AMERICA INTELLECTUAL PROPERTY CORPORATION, P.O. BOX 506, MERRIFIELD, VA, 22116, US

(21) Appl. No.: 11/934,044

(22) Filed: Nov. 1, 2007

(30) Foreign Application Priority Data
May 29, 2007 (TW) 096119109

(51) Int. Cl. H01L 21/336

(52) U.S. Cl. 438/300; 257/E21.409

(57) ABSTRACT

A method of manufacturing a self-aligned fin FET (FinFET) device is disclosed, in which, an insulating layer of a shallow trench isolation is etched back to partially expose sidewalls of the semiconductor substrate surrounded by the shallow trench isolation, and the sidewalls of the semiconductor substrate are then isotropically etched, allowing the semiconductor substrate to form into a relatively thin fin structure for forming a three-dimensional gate structure having three faces.

### BACKGROUND OF THE INVENTION

1. Field of the Invention

The present invention relates to a method of manufacturing a semiconductor device, and particularly to a method of manufacturing a self-aligned fin field effect transistor (FinFET) device.

2. Description of the Prior Art

In recent years, as various kinds of consumption electronic products being constantly towards miniaturization development, the size of semiconductor components is hoped to reduce, in order to accord with high integration, high performance, low power consumption, and the demand of products.

Dynamic random access semiconductor memories (DRAMs) contains a matrix of memory cells connected up in the form of rows via word lines and columns via bit lines. Data are read from the memory cells or written to the memory cells by the activation of suitable word and bit lines. A dynamic memory cell generally comprises a selection transistor and a storage capacitor, the selection transistor usually being configured as a horizontally designed field-effect transistor and comprising two diffusion regions separated by a channel above which a gate is arranged. The gate is then connected to a word line. One of the diffusion regions of the selection transistor is connected to a bit line and the other diffusion region is connected to the storage capacitor. By the application of a suitable voltage via the word line to the gate, the selection transistor turns on and enables a current flow between the diffusion regions in order to charge the storage capacitor via the bit line.

However, with the miniaturization development of the electronic products, there is a development for fin field effect transistors (FETs) to achieve a high drive current and to lessen short channel effect. Because the fin FET basically has a three-dimensional structure, more complicated than a traditional structure, it is more difficult to make.

Therefore, there is still a need for a novel method of manufacturing a fin FET device.

### SUMMARY OF THE INVENTION

Accordingly, one objective of the present invention is to provide a method of manufacturing a self-aligned fin FET device, to obtain a FET having a fin structure thinner than that of the prior art.

The method of manufacturing a self-aligned fin FET device according to the present invention comprises steps as follows. First, a semiconductor substrate is provided. An active area is defined as a fin structure, and trenches are defined on both sides of the active area in the semiconductor substrate, wherein a gate region is located on a middle part of the active area. An insulation layer is formed to fill the trenches. Thereafter, a portion of the insulation layer in the trenches at both sides of the gate region is etched back to expose an upper portion of the fin structure in the gate region. Finally, a gate material is formed to cover the upper portion of the fin structure in the gate region.

In accordance with another aspect of the present invention, the method of manufacturing a self-aligned fin FET device according to the present invention comprises steps as follows. First, a semiconductor substrate is provided. A first hard mask is formed on the semiconductor substrate. The first hard mask has a pattern. A region of the semiconductor substrate covered by the first hard mask is defined as an active area. The active area comprises a gate region located in a middle part of the active area. A region of the semiconductor substrate not covered by the first hard mask comprises a word line region and a shallow trench isolation region. Next, a region of the semiconductor substrate not covered by the hard mask is etched to form a trench, and thereby a region of the semiconductor substrate covered by the first hard mask is formed into a fin structure. Thereafter, an insulation layer is formed to fill the trench. The insulation layer located in the shallow trench isolation region is etched back by a microlithography and etching process until a height of the insulation layer is substantially the same as that of the bottom of the first hard mask. Thereafter, a second hard mask is formed on the insulation layer located in the shallow trench isolation region. An upper portion of the insulation layer in the word line region is etched back, using the first hard mask and the second hard mask as a mask, to expose an upper portion of the fin structure in the gate region of the active area. Thereafter, sidewalls of the upper portion of the fin structure in the gate region are isotropically etched. The first hard mask and the second hard mask are removed. Finally, a gate material is formed to fill the word line region and cover the gate region to form a word line.

In comparison with the prior art, the unit area of the device obtained by the method of manufacturing a self-aligned fin FET device according to the present invention can be reduced and the integration can be increased, since the active area of the device has a quite thin fin structure. Furthermore, on-current gain can be increased due to the three-dimensional junction between the control gate and the fin structure of the active area, while the contact of the bit line with the source/drain is not affected and still good.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-10 illustrate an embodiment of the method of manufacturing a self-aligned fin FET device according to the present invention; and

FIG. 11 illustrates a schematic plan view of a part of a memory cell in a DRAM array having the fin FETs made by the method according to the present invention.

### DETAILED DESCRIPTION

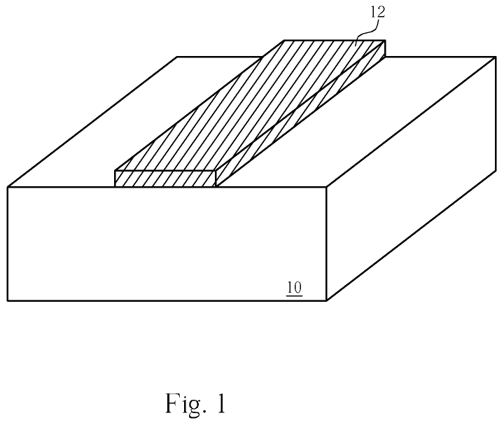

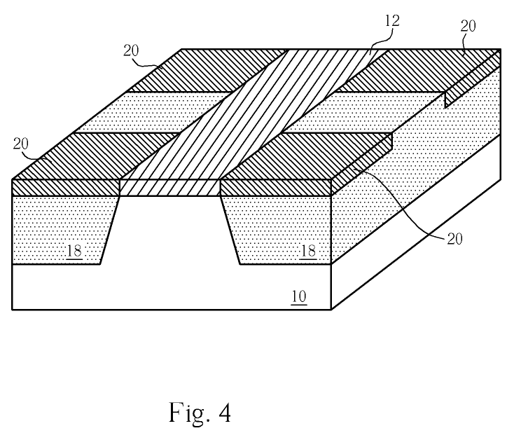

FIGS. 1-10 illustrate an embodiment of the method of manufacturing a self-aligned fin FET device according to the present invention. Please refer to FIG. 1. First, a semiconductor substrate 10 is provided. The semiconductor substrate may comprise for example silicon, germanium, carbon-silicon, silicon-on-insulator (SOI), silicon germanium-on-insulator (SGOI), compound semiconductor, multilayer semiconductor, or any combination thereof. A hard mask 12 is formed on the semiconductor substrate 10. The hard mask 12 has a pattern. The hard mask 12 may be formed through depositing a silicon nitride compound layer (such as a silicon nitride layer) on the semiconductor substrate 10 and patterning the silicon nitride compound layer by a microlithography and etching process. A region of the semiconductor substrate 10 covered by the hard mask 12 is defined as an active area. The active area comprises a gate region, and further comprises a source region and a drain region. The gate region is disposed on the middle part of the active area. The source region and the drain region are disposed in the active area at two sides of the gate region, respectively. A region of the semiconductor substrate 10 not covered by the hard mask 12 comprises a word line region and a shallow trench isolation region.

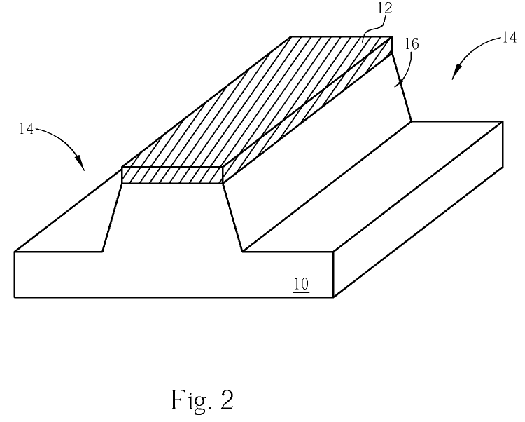

Next, please refer to FIG. 2. The region of the semiconductor substrate 10 not covered by the hard mask 12 is subjected to an anisotropic etching process, for example, a dry etching, to downwardly form trenches 14 (the trenches 14 are partially shown in FIG. 2). Thus, the region of the semiconductor substrate 10 covered by the hard mask 12 (i.e. the active area) is formed into a fin structure 16. The trenches 14 surround the fin structure 16.

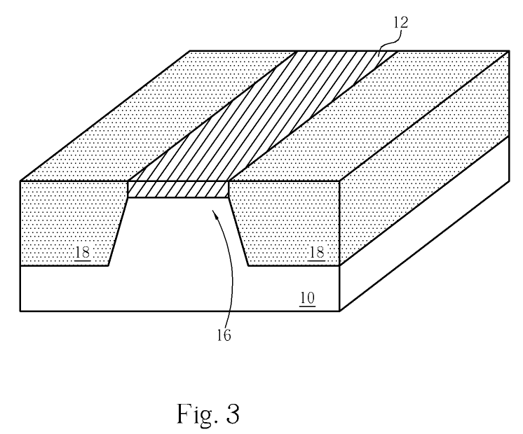

Please refer to FIG. 3. An insulation layer 18 is formed to fill the trenches 14. The filling of the insulation layer 18 may be performed by for example a chemical vapor deposition process, and the material of insulation layer may be, for example, oxide, nitride, or oxy-nitride. The insulation layer is deposited to fill the trenches 14 and cover the hard mask 12, and then the surface of the resulting insulation layer is planarized by a chemical mechanical polishing process to expose the hard mask 12.

In the method of the present invention, in order to make a fin gate, a portion of the insulation layer at each of two sides of the gate region is removed to expose a part of the upper portion of the fin structure. The space thus obtained serves as a word line region for the subsequent manufacture of a word line. Accordingly, the word line can be disposed to cross the gate structure, and, moreover, the word line contacts the gate structure with three faces. The removal of the portion of the insulation layer of the gate region may be performed by etching. That is, the portion not to be removed by etching (for example, the portion to be remained as a shallow trench isolation in the subsequent process) is covered by a hard mask, and the portion to be removed (i.e. the portion of the insulation layer at each of the two sides of the gate region) is exposed and, thereafter, removed by an anisotropic etching process. The hard mask may be formed by performing a microlithography and etching process. For example, a photoresist layer (not shown) is formed over the insulation layer 18 and the hard mask 12 and patterned to expose the portions which will be covered by the pattern of the second hard mask in the subsequent process. An etching back process is performed to remove a depth of the exposed portions, such that the height of the exposed portions is at a level substantially the same as the bottom of the hard mask 12. Thereafter, a hard mask layer is deposited conformally on the insulation layer 18 and the hard mask 12, and then planarized, forming a hard mask 20. The hard mask 20 covers the portions of the insulation layer in the shallow trench isolation regions to shield these regions in a subsequent etching process.

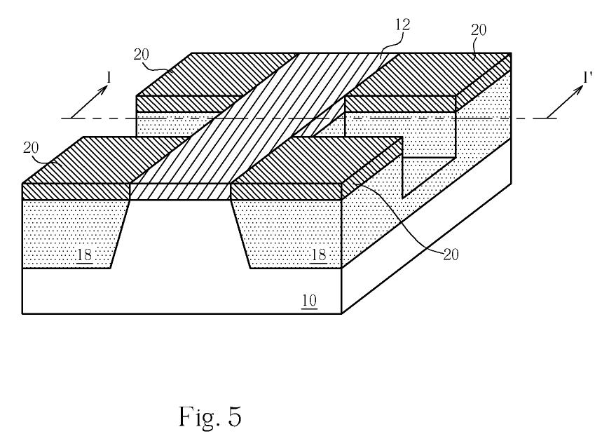

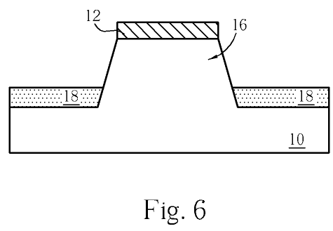

Thereafter, as shown in FIG. 5, an upper portion of the insulation layer 18 at two sides of the gate region (that is, the upper portion of the insulation layer in the word line region) is etched back using the hard mask 12 and the hard mask 20 as a mask for etching, and thereby to expose the upper portion of the fin structure 16 in the gate region of the active area. The method of etch may be, for example, a dry etching. The thickness of the fin structure 16 in the gate region may be for example 60 nm, and the height may be for example 60 nm, but not limited thereto. FIG. 6 illustrates a schematic cross-sectional view along the line I-I′ in FIG. 5.

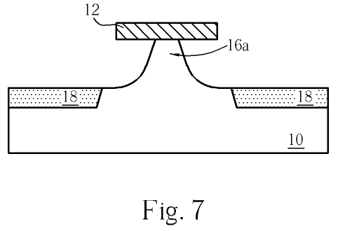

Please refer to FIG. 7. Thereafter, sidewalls of the fin structure 16 are isotropically etched to reduce the thickness of the fin structure 16, becoming the fin structure 16a as shown in FIG. 7. The method of isotropic etch may be for example wet etch. For example, if the fin structure has an original thickness of 60 nm, each side is reduced about 15 nm after the isotropic etch, leading the fin structure 16a to have a thickness of about 30 nm.

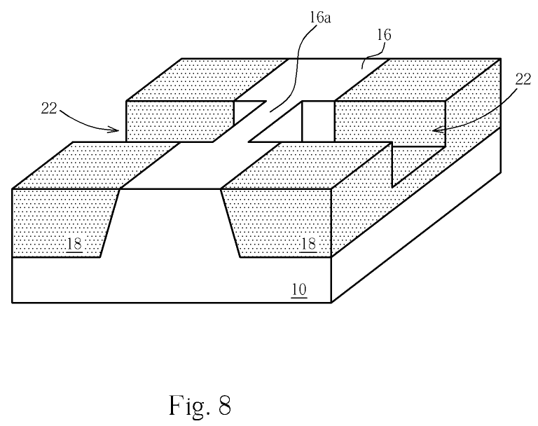

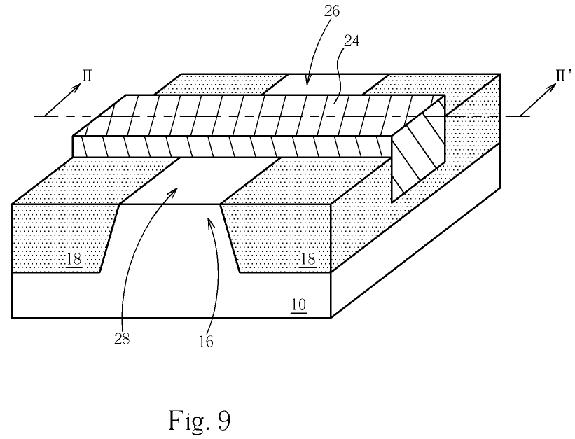

Please refer to FIG. 8. Thereafter, the hard masks 12 and 20 are removed. The recesses obtained after the etching serve as word line regions 22. Thereafter, referring to FIG. 9, a gate material is formed to fill the word line regions 22 and cover the gate region to become a word line 24, thereby the gate material (i.e. the word line) clings onto the two opposite sides and the top face of the fin structure 16a in the gate region. The word line may be formed by, for example, conformally depositing a gate material, for example, polysilicon, to fill the recesses of the word line regions 22 and cover the active area and the shallow trench isolation region, and then retaining only the gate material in the word line regions and above the gate region. Thereby, a word line 24 passing the gate region is formed. Finally, a source and a drain are formed in the source region 26 and the drain region 28 at two sides of the word line 24, respectively, to form a fin FET device.

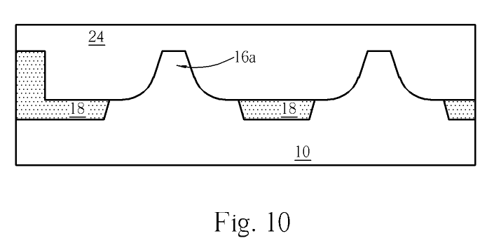

FIG. 10 illustrates a schematic cross-sectional view along the line II-II′ in FIG. 9. There is a word line 24 disposed on the top surface of the fin structure 16a.

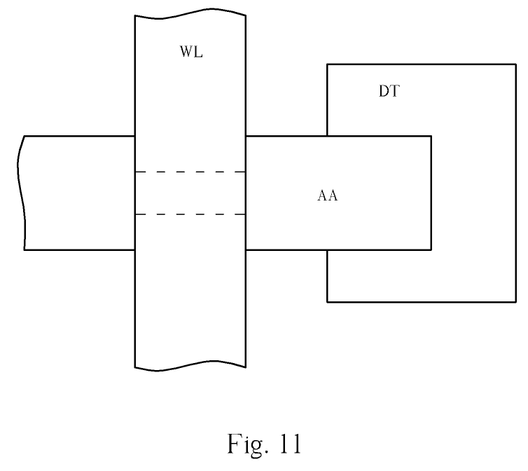

The method of manufacturing a self-aligned fin FET device according to the present invention may be used in manufacture of a DRAM array, such as, a checkerboard deep trench dynamic random access memory cell array. FIG. 11 illustrates a schematic plan view of a part of a memory cell in a DRAM array having the fin FETs made by the method according to the present invention. The word lines WL (including control gates) are disposed to cross the active areas AA. The deep trench capacities DT are electrically connected with sources/drains of the active areas AA. The active areas AA each have a fin structure which is thinner at the intersection with the word line WL, indicating the main characteristic of the present invention.

Those skilled in the art will readily observe that numerous modifications and alterations of the device and method may be made while retaining the teachings of the invention.

1. A method of manufacturing a self aligned fin FET (FinFET) device, comprising:
providing a semiconductor substrate;
defining an active area as a fin structure and trenches on both sides of the active area in the semiconductor substrate, wherein a gate region is located on a middle part of the active area;
forming an insulation layer to fill the trenches;
etching back a portion of the insulation layer in the trenches at both sides of the gate region to expose an upper portion of the fin structure in the gate region; and
forming a gate material to cover the upper portion of the fin structure in the gate region.

2. The method of manufacturing a self aligned fin FET device of claim 1 further comprising an etching process to narrow down the fin structure in the gate region, before the gate material forming step.

3. The method of manufacturing a self aligned fin FET device of claim 1, wherein the active area defining step comprising:
forming a hard mask on the semiconductor substrate, wherein, the hard mask has a pattern, a region of the semiconductor substrate covered by the hard mask is defined as an active area; and
etching a region of the semiconductor substrate not covered by the hard mask to form trenches on both sides of the active area, such that the active area of the semiconductor substrate covered by the hard mask is formed into a fin structure.

4. The method of manufacturing a self aligned fin FET device of claim 3, wherein the hard mask comprises a silicon nitride compound.

5. The method of manufacturing a self-aligned fin FET device of claim 1, wherein the gate material comprises polysilicon.

6. The method of manufacturing a self aligned fin FET device of claim 1, wherein the semiconductor substrate comprises silicon.

7. The method of manufacturing a self aligned fin FET device of claim 1, wherein the insulation layer comprises oxide, nitride, or oxy-nitride.

8. The method of manufacturing a self-aligned fin FET device of claim 3 further comprising:
forming a source and a drain in the active area at both sides of the gate material, respectively.

9-16. (canceled)
